(19) United States
(12) Patent Application Publication
(10) Pub. No.: US 2024/0123730 A1
(43) Pub. Date: Apr. 18, 2024

(54) CONNECTION UNIT, INKJET HEAD ASSEMBLY INCLUDING A CONNECTION UNIT AND METHOD OF ASSEMBLING AN INKJET HEAD ASSEMBLY

(71) Applicant: SEMES CO., LTD., Cheonan-si (KR)

(72) Inventors: Hochul PARK, Suwon-si (KR); Eunji CHOI, Cheonan-si (KR)

(73) Assignee: SEMES CO., LTD., Cheonan-si (KR)

(21) Appl. No.: 18/470,907

(22) Filed: Sep. 20, 2023

(30) Foreign Application Priority Data
Oct. 12, 2022 (KR) 10-2022-0130142

(51) Int. Cl. B41J 2/14; B41J 2/16

(52) U.S. Cl. CPC B41J 2/14; B41J 2/16

(57) ABSTRACT

An ink jet head assembly for providing a chemical liquid onto a substrate may include a head pack having ink jet heads mounted therein, a head plate coupled to the head pack, and a connection unit configured to provide an electrical connection between the head pack and the head plate. The connection unit may include a first board disposed on an upper face of a head pack having an ink jet head therein and a second board disposed on a bottom face of a head plate coupled to the head pack. The second board may face the first board. The first board and the second board may be connected to each other in a board-to-board manner when the head pack is combined with the head plate.

### CROSS-REFERENCE TO RELATED APPLICATION

This application claims priority to Korean Patent Application No. 10-2022-0130142 filed on Oct. 12, 2022 in the Korean Intellectual Property Office (KIPO), the contents of which are herein incorporated by reference in its entirety.

### BACKGROUND

### 1. Field

Example embodiments of the invention relate to a connection unit, an inkjet head assembly and a method of assembling an inkjet head assembly. More particularly, example embodiments of the invention relate to a connection unit for combining a head pack with a head plate, an ink jet head assembly including such a connection unit, and a method of assembling the ink jet head assembly having the connection unit.

### 2. Related Technology

A process of providing a chemical liquid may be performed to manufacture a display device such as an organic light emitting display (OLED) device. Such a process is usually carried out using an ink jet head assembly including ink jet heads.

The conventional ink jet head assembly may include a head pack having ink jet heads for providing a chemical liquid onto a substrate and a head plate coupled to the head pack. The head pack and the head plate may be electrically connected to each other using a cable.

If a plurality of ink jet heads are mounted in the head pack, the number of cables corresponding to the number of the ink jet heads may be required, and thus the time for combining the head pack with the head plate may be increased and the configuration of the ink jet head assembly may be complicated. Further, if the head pack is coupled to the head plate using a screw, the arrangement of the ink jet heads may vary by the force applied to the screw. As a result, the time for the process performed using the ink jet head assembly may be increased and also the exact amount of the chemical liquid may not be provided onto the substrate.

### SUMMARY

One aspect of the invention provides a connection unit capable of easily combining a head pack with a head plate.

Another aspect of the invention provides an inkjet head assembly including a connection unit capable of easily combining a head pack with a head plate

Still another aspect of the invention provides a method of assembling which may easily combine a head pack with a head plate

According to one aspect of the invention, there is provided a connection unit for an ink jet head assembly. The connection unit may include a first board disposed on an upper face of a head pack having an ink jet head therein, and a second board disposed on a bottom face of a head plate coupled to the head pack. The second board may substantially face the first board. In this case, the first board and the second board may be connected to each other in a board-to-board manner when the head pack is combined with the head plate.

In example embodiments, the first board may include a first connector and the second board may include a second connector substantially corresponding to the first connector. For example, the first connector may include a substantial male connector and the second connector may include a substantial female connector.

According to another aspect of the invention, there is provided an ink jet head assembly for providing a chemical liquid onto a substrate. The ink jet head assembly may include a head pack having ink jet heads mounted therein, a head plate coupled to the head pack, and a connection unit configured to provide an electrical connection between the head pack and the head plate. The connection unit may include a first board disposed on an upper face of a head pack having an ink jet head therein, a second board disposed on a bottom face of a head plate coupled to the head pack. The second board may substantially face the first board. Here, the first board and the second board are connected to each other in a board-to-board manner when the head pack is combined with the head plate.

In example embodiments, the first board may include a first connector and the second board may include a second connector substantially corresponding to the first connector.

In example embodiments, the first connector may include a substantial male connector and the second connector may include a substantial female connector.

In some example embodiments, the first connector may include a substantial female connector and a substantial male connector, and the second connector may include a substantial male connector and a substantial female connector, respectively.

In example embodiments, the head pack may be combined with the head plate such that a bottom face of the head plate may substantially face an upper face of the head pack.

In some example embodiments, the head pack may include at least two ink jet heads and a first plate on which the at least two ink jet heads are mounted, and the head plate may include a second plate facing the first plate. In this case, the first board may be disposed over the first plate and the second board may be disposed on a bottom face of the second plate.

In some example embodiments, the ink jet head assembly may additionally include a connecting part configured to help a coupling between the head pack and the head plate.

The connecting part may be configured to combine the head pack with the head plate utilizing an air suction mechanism.

In some example embodiments, the ink jet head assembly may additionally include a disconnecting part configured to help a decoupling between the head pack and the head plate.

According to example embodiments, a method of assembling an ink jet head assembly is provided. In the method of assembling an ink jet head assembly, a head pack including ink jet heads may be placed to substantially face a head plate. A first board may be combined with a second board in a board-to-board manner such that the head pack may be coupled to the head plate. The first board may be disposed on an upper face of the head pack and the second board may be disposed on a bottom face of the head plate.

In example embodiments, the combining of the first board with the second board may include combining at least one first connector of the first board with at least one second connector of the second board.

In some example embodiments, the at least one first connector may include at least one of a female connector and a male connector, and the at least second first connector may include at least one of a male connector and a female connector.

In some example embodiments, the combining of the first board with the second board may include enhancing a coupling between the head pack and the head plate using a connecting part.

In some example embodiments, the method of assembling an ink jet head assembly may additionally include disconnecting the head pack from the head plate.

In some example embodiments, a providing of an electrical signal to the head pack and the head plate may be stopped and a chemical liquid supply line may be separated from the ink jet heads when the head pack is disconnected from the head plate.

In some example embodiments, the disconnecting of the head pack from the head plate may include using a disconnecting member configured to help a decoupling between the head pack and the head plate.

In some example embodiments, a chemical liquid supply line may be connected to the ink jet heads and an electrical signal may be provided to the head pack and the head plate when the head pack is coupled to the head plate.

According to example embodiments of the invention, the coupling between the head pack and the head plate may be accomplished utilizing the board-to-board manner such that the head pack may be easily combined with the head plate while improving the connection stability between the head pack and the head plate. Therefore, the time of the process performed using the ink jet head assembly may be reduced and the productivity of the integrated circuit device or the display device manufactured using the ink jet head assembly may be improved. Further, the electrical signal may be stably provided to the head pack and the head plate coupled to each other in the board-to-board manner so that the exact amount of the chemical liquid may be provided onto the desired regions of the substrate. Therefore, the reliability of the integrated circuit device or the display device may be improved.

### BRIEF DESCRIPTION OF THE DRAWINGS

Example embodiments will be more clearly understood from the following detailed description taken in conjunction with the accompanying drawing. The following figures represent non-limiting, example embodiments as described herein.

FIG. 1 is a perspective view illustrating an inkjet head assembly including a connection unit in accordance with example embodiments of the invention.

FIG. 2 is a schematic cross-sectional view illustrating an inkjet head assembly including a connection unit in accordance with example embodiments of the invention.

FIG. 3 is a flow chart illustrating a method of assembling an inkjet head assembly in accordance with example embodiments of the invention.

### DESCRIPTION OF EMBODIMENTS

Various embodiments will be described more fully hereinafter with reference to the accompanying drawings, in which some embodiments are shown. The invention may, however, be embodied in many different forms and should not be construed as limited to the embodiments set forth herein. Rather, these embodiments are provided so that this description will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (for example, rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include a plurality of forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the face through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

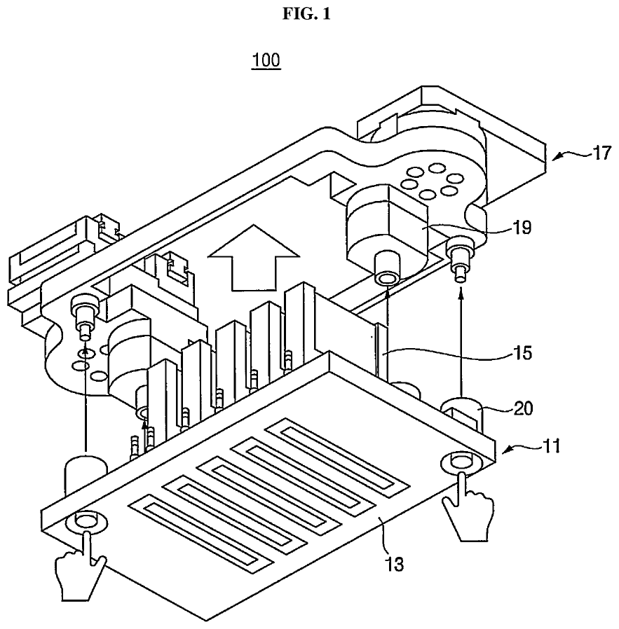

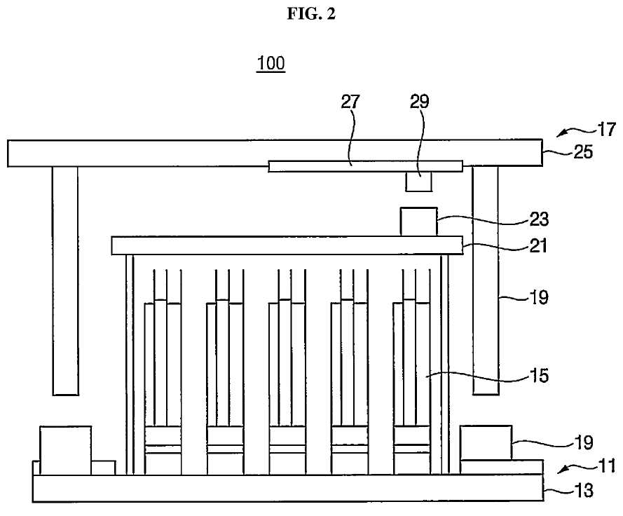

FIG. 1 is a perspective view illustrating an inkjet head assembly including a connection unit in accordance with example embodiments of the invention. FIG. 2 is a schematic cross-sectional view illustrating an inkjet head assembly including a connection unit in accordance with example embodiments of the invention.

Referring to FIG. 1 and FIG. 2, an inkjet head assembly 100 according to example embodiments may be employed in processes of manufacturing a display device such as an organic light emitting display (OLED) device, a quantum dot light emitting display (QLED) device, etc. For example, the ink jet head assembly 100 may perform a process of providing a chemical liquid onto a substrate to form predetermined pixels on the substrate, a process of supplying a chemical liquid onto a substrate to form an encapsulation layer covering predetermined circuits formed on the substrate.

In example embodiments, the ink jet head assembly 100 may include a head pack 11, an ink jet head 15, a head plate 17 and a connection unit. In this case, the connection unit may provide an electrical connection between the head pack 11 and the head plate 17.

The ink jet head 15 may provide the chemical liquid onto the substrate and may be mounted on the head pack 11. In example embodiments, the ink jet head assembly 100 may include a plurality of ink jet heads 15 mounted on the head pack 11. Although five inkjet heads 15 are illustrated, the invention is not limited thereto. Here, each of the ink jet heads 15 may be mounted on the head pack 11 so that a nozzle face of each ink jet head 15 may face the substrate. The head pack 11 having the ink jet heads 15 may be combined with the head plate 17. The plurality of ink jet heads 15 may be arranged in previously set positions according to the combination of the head plate 17 and the head pack 11.

In example embodiments, the operation of the ink jet head 15 may be advantageously controlled such that the exact amount of chemical liquid may be exactly provided onto the desired regions of the substrate while the ink jet head assembly 100 performs the process of providing the chemical liquid onto the substrate. To this end, the connection unit may provide the electrical connection between the head pack 11 and the head plate 17 through electrical signals. In other words, the connection unit of the ink jet head assembly 100 may provide the electrical signal coupled to the ink jet heads 15 through the head plate 17 and the head pack 11 so as to control the operations of the ink jet heads 15.

In example embodiments, the connection unit of the ink jet head assembly 100 may include a first board 21 and a second board 27. The first board 21 may be disposed on the head pack 11 and the second board 27 may be disposed on the head plate 17. For example, the first board 21 may be placed on an upper face of the head pack and the second board 27 may be positioned on a bottom face of the head plate 17. Here, the first board 21 may substantially face the second board 27. Further, the first board 21 may be electrically connected to the ink jet head 15 and the second board 27 may be electrically connected to a control member (not illustrated) of the ink jet head assembly 100.

In example embodiments, the first board 21 and the second board 27 may be connected to each other in a board-to-board manner when the head plate 17 is combined with the head pack 11. To this end, the first board 21 may include a first connector 23 and the second board 27 may include a second connector 29 coupled to the first connector 23. For example, the first connector 23 of the first board 21 may have a substantial female connector structure while the second connector 27 of the second board 27 may have a substantial male connector structure. Alternatively, the first connector 23 of the first board 21 may have a substantial male connector structure whereas the second connector 27 of the second board 27 may have a substantial female connector structure.

In example embodiments, as shown in FIG. 2, the first connector 23 may be disposed at a portion of the first board 21 and the second connector 29 may be located at a portion of the second board 27 corresponding to the portion of the first board 21 in order to couple the first board 21 with the second board 27 in the above-mentioned board-to-board manner. For example, the first connector 23 and the second connector 29 may be located at the same position in the ink jet head assembly 100 when the first connector 23 is coupled to the second connector 29.

In the ink jet head assembly 100 according to example embodiments, the first board 21 and the second board 27 may be disposed to each other within an error range below about ±0.5 millimeters. Further, the head pack 11 and the head plate 17 may be combined with each other by an error less than about 5 micrometers.

As describe above, in the ink jet head assembly 100 according to example embodiments, the head pack 11 and the head plate 17 may be combined with the board-to-board manner when the head pack 11 is coupled to the head plate 17. Therefore, the time for coupling the head pack 11 to the head plate 17 may be considerably reduced and the connection stability between the head pack 11 and the head plate 17 may be greatly improved.

In some example embodiments, the head plate 17 may be fixed in the ink jet head assembly 100 and the head pack 11 may be replaceable. For example, as the ink jet head assembly 100 performs the process of providing the chemical liquid onto the substrate, the head pack 11 may be replaced with a new head pack if the chemical liquid is consumed or in an abnormal condition. In this case, the head pack 11 may be dissembled from the fixed head plate 17, and then the new head pack may be coupled to the fixed head plate 17 in the above board-to-board manner.

More specifically, as illustrated in FIG. 2, the head pack 11 may include a first plate 13 and at least two ink jet heads 15. The head plate 17 may include a second plate 25 substantially corresponds to the first plate 13. The at least two ink jet heads 15 may be mounted on the first plate 13. However, the number of the ink jet heads 15 may vary in accordance with the dimensions of the ink jet head assembly 100. In this case, the first board 21 may be disposed on the at least two ink jet heads 15 and the second board 27 may be located on the bottom face of the second plate 25. Thus, the first board 21 may substantially face the second board 27. As described above, because the first board 21 and the second board 27 may include the first connector 23 and the second connector 29 having the substantially corresponding structures, respectively, the new head pack 11 having the above described configuration may be coupled to the head plate 17 for a relatively short time with the improved connection stability.

In the conventional ink jet head assembly, a head pack and a head plate are arranged such that the bottom face of the head pack faces the upper face of the head plate, and then the head pack is coupled to the head plate. However, the board-to-board manner may not be employed in the coupling of the head pack and the head plate since the nozzle face of the ink jet head is positioned under the head pack. In contrast, according the example embodiments of the invention, the head pack 11 and the head plate 17 may be combined with each other while facing the upper face of the head pack 11 with the bottom face of the head plate 17. Therefore, the head pack 11 and the head plate 17 may be coupled with each other in the board-to-board manner while excluding the interference by the nozzle faces of the ink jet heads 15 positioned under the head pack 11.

In some example embodiments, the ink jet head assembly 100 may additionally include a connecting part 19 for more improving the connection stability between the head pack 11 and the head plate 17.

As illustrated in FIG. 2, the connecting part 19 of the ink jet head assembly 100 may be disposed between the head pack 11 and the head plate 17. The connecting part 19 may include a first portion connected to the head pack 11 and a second portion of the head plate 17. When the head pack 11 is coupled to the head plate 17, the first portion of the connecting part 19 and the second portion of the connecting part 19 may be engaged with other. For example, the first and the second portions of the connecting part 19 may have together an air lock configuration utilizing an air suction mechanism. In other words, the connecting part 19 may serve in the coupling the head pack 11 using the air suction mechanism. Using the connecting part 1 having such a configuration, the head pack 11 and the head plate 17 may be more firmly combined with each other. In particular, the connecting part 19 may help the combination of the head pack 11 and the head plate 17 utilizing the air suction mechanism so that the arrangement of the ink jet heads 15 may be stably maintained in comparison with the head pack 11 and the head plate 17 coupled to each other using a screw.

In some example embodiments, the ink jet head assembly 100 may additionally include a disconnecting part 20 for serving the decoupling of the head pack 11 and the head plate 17. If the connecting part 19 helps the coupling of the head pack 11 and the head plate 17 using the air suction mechanism, the disconnecting part 20 may help the decoupling of the head pack 11 and the head plate 17 utilizing an air release mechanism. Thus, the disconnecting part 20 may be adjacent to the connecting part 19. Particularly, the disconnecting part 20 may serve in the decoupling of the head pack 11 and the head plate 17 by pushing up the head pack 11 away from the head plate 17. Therefore, the head pack 11 may be more easily disconnected from the head plate 17 using the disconnecting part 20.

As described above, in the ink jet head assembly 100 according to some example embodiments, the connecting part 19 may more stably connect the head pack 11 with the head plate 17 and the disconnecting part 20 may more easily separate the head pack 11 from the head plate 17. Therefore, the connection stability between the head pack 11 and the head plate 17 may be enhanced even though the ink jet head assembly 100 includes more ink jet heads 15 mounted in the head pack 15. Further, such a head pack 11 may be more rapidly and stably separated from the head plate 17.

Although FIG. 2 illustrates the configuration in which the first board 21 includes the first connector 23 and the second board 27 includes the second connector 29, the invention is limited thereto. In some example embodiments, the first board 21 may include more than two first connectors 23 and also the second board 27 may include more than two second connectors 29 corresponding to the more than two first connectors 23, respectively. When each of the first board 21 and the second board 27 includes each of the more than two first connectors 23 and the more than two second connectors 29, the combination between the head pack 11 and the head plate 17 may be stably maintained if the number of the ink jet heads 15 disposed in the head pack 11 is increased.

In other example embodiments, the first connectors 23 of the first board 21 may include at least one female connector and at least one male connector. Further, the second connectors 29 of the second board 27 may include at least one male connector and at least one female connector corresponding to the at least one female connector and the at least one male connector of the first connectors 23, respectively. Therefore, the connection stability between the head pack 11 and the head plate 17 may be more increased.

Hereinafter, it will be described a method of assembling an ink jet head assembly in accordance with example embodiments of the invention. More specifically, a process of combining the head pack 11 with the head plate 17 as illustrated in FIGS. 1 and 2 will be described, and also a process of disconnecting the head pack 11 from the head plate 17 will be described.

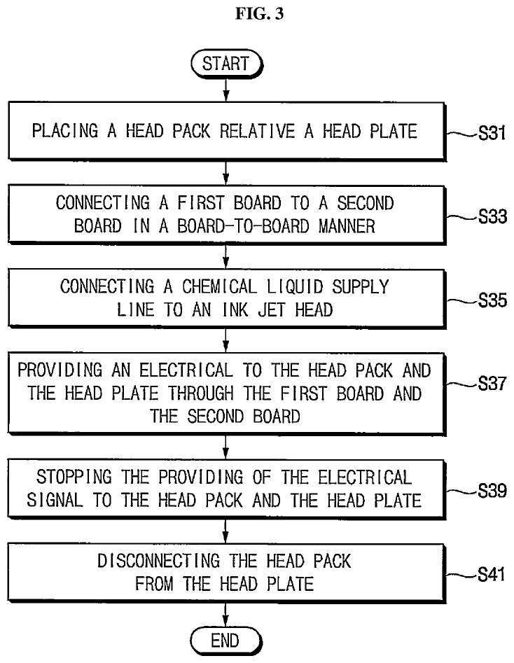

FIG. 3 is a flow chart illustrating the method of assembling the ink jet head assembly 100.

Referring to FIG. 3, the head pack 11 may be placed relative to the head plate 17 such that the head pack 11 may be substantially faced with the head plate 17 (step S31). At this time, the upper face of the head pack 11 may substantially face the bottom face of the head plate 17. Further, the first board 21 disposed on the upper face of the head pack 11 may substantially face the second board 27 disposed on the bottom face of the head plate 17. In this case, the first board 21 may be electrically connected to the head pack 11 and the second board 27 may be electrically connected to the head plate 17.

In example embodiments, the first board 21 may be connected to the second board 27 by the board-to-board manner (step S33). More specifically, the at least one first connector 23 may be combined with the at least one second connector 29 of the second board 27. For example, the first connectors 23 including the female connector and the male connector may be combined with the second connectors 29 including the male connector and the female connector, respectively. In some example embodiments, the head pack 11 may be more strongly coupled to the head plate 17 using the connecting part 19. The connecting part 19 may enhance the coupling of the head pack 11 and the head plate 17 utilizing the air suction mechanism.

Subsequently, a chemical liquid supply line may be connected to the ink jet head 15 to provide the chemical liquid to the ink jet head 15 (step S35). Simultaneously, the electrical signal may be provided to the head pack 11 and the head plate 17 through the first board 21 and the second board 27 (step S37). Therefore, the head pack 11 and the head plate 18 may be exactly combined with each other and the control part of the ink jet head assembly 100 may exactly control the operation of the ink jet head 15 mounted in the head pack 11. As a result, the exact amount of the chemical liquid may be provided onto the desired regions of the substrate.

When the head pack 11 is replaced with the new head pack, the providing of the electrical signal to the head pack 11 and the head plate 17 may be stopped (step S39). Then, the chemical liquid supply line may be separated from the ink jet head 15 and the head pack 11 may be disconnected from the head plate 17 (step S41). At this time, the decoupling of the head pack 11 and the head plate 17 may be easily and rapidly accomplished using the disconnecting part 20.

Then, the new head pack may be coupled to the head plate 17 by repeating the step 31 to the step S37 as describe above.

According to example embodiments of the invention, the coupling between the head pack and the head plate may be accomplished utilizing the board-to-board manner such that the head pack may be easily combined with the head plate while improving the connection stability between the head pack and the head plate. Therefore, the time of the process performed using the ink jet head assembly may be reduced and the productivity of the integrated circuit device or the display device manufactured using the ink jet head assembly may be improved. Further, the electrical signal may be stably provided to the head pack and the head plate coupled to each other in the board-to-board manner so that the exact amount of the chemical liquid may be provided onto the desired regions of the substrate. Therefore, the reliability of the integrated circuit device or the display device may be improved. The ink jet head assembly including such connection unit may be advantageously used to the processes of manufacturing an integrated circuit device or a display device.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the invention. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A connection unit for an ink jet head assembly, which comprises:
a first board disposed on an upper face of a head pack having an ink jet head therein;
a second board disposed on a bottom face of a head plate coupled to the head pack, the second board facing the first board,
wherein the first board and the second board are connected to each other in a board-to-board manner when the head pack is combined with the head plate.

2. The connection unit of claim 1, wherein the first board includes a first connector and the second board includes a second connector corresponding to the first connector.

3. The connection unit of claim 2, wherein the first connector includes a substantial male connector and the second connector includes a substantial female connector.

4. An ink jet head assembly for providing a chemical liquid onto a substrate, which comprises:
a head pack having ink jet heads mounted therein;
a head plate coupled to the head pack; and
a connection unit configured to provide an electrical connection between the head pack and the head plate, the connection unit comprising:
a first board disposed on an upper face of a head pack having an ink jet head therein;
a second board disposed on a bottom face of a head plate coupled to the head pack, the second board facing the first board,
wherein the first board and the second board are connected to each other in a board-to-board manner when the head pack is combined with the head plate.

5. The ink jet head assembly of claim 4, wherein the first board includes a connector and the second board includes a second connector corresponding to the first connector.

6. The ink jet head assembly of claim 5, wherein the first connector includes a substantial male connector and the second connector includes a substantial female connector.

7. The ink jet head assembly of claim 5, wherein the first connector includes a substantial female connector and a substantial male connector, and the second connector includes a substantial male connector and a substantial female connector, respectively.

8. The ink jet head assembly of claim 4, wherein the head pack is combined with the head plate such that a bottom face of the head plate substantially faces an upper face of the head pack.

9. The ink jet head assembly of claim 8, wherein the head pack includes at least two ink jet heads and a first plate on which the at least two ink jet heads are mounted, the head plate includes a second plate facing the first plate, the first board is disposed over the first plate, and the second board is disposed on a bottom face of the second plate.

10. The ink jet head assembly of claim 4, further comprising a connecting part configured to help a coupling between the head pack and the head plate.

11. The ink jet head assembly of claim 10, wherein the connecting part is configured to combine the head pack with the head plate utilizing an air suction mechanism.

12. The ink jet head assembly of claim 4, further comprising a disconnecting part configured to help a decoupling between the head pack and the head plate.

13. A method of assembling an ink jet head assembly, which comprises:
placing a head pack including ink jet heads to face a head plate; and
combining a first board with a second board in a board-to-board manner such that the head pack is coupled to the head plate,
the first board is disposed on an upper face of the head pack and the second board is disposed on a bottom face of the head plate.

14. The method of assembling an ink jet head assembly of claim 13, wherein the combining of the first board with the second board comprises combining at least one first connector of the first board with at least one second connector of the second board.

15. The method of assembling an ink jet head assembly of claim 14, wherein the at least one first connector includes at least one of a female connector and a male connector, and the at least second first connector includes at least one of a male connector and a female connector.

16. The method of assembling an ink jet head assembly of claim 13, wherein the combining of the first board with the second board comprises enhancing a coupling between the head pack and the head plate using a connecting part.

17. The method of assembling an ink jet head assembly of claim 13, further comprising disconnecting the head pack from the head plate.

18. The method of assembling an ink jet head assembly of claim 17, wherein a providing of an electrical signal to the head pack and the head plate is stopped and a chemical liquid supply line is separated from the ink jet heads when the head pack is disconnected from the head plate.

19. The method of assembling an ink jet head assembly of claim 17, the disconnecting of the head pack from the head plate comprises using a disconnecting member configured to help a decoupling between the head pack and the head plate.

20. The method of assembling an ink jet head assembly of claim 13, wherein a chemical liquid supply line is connected to the ink jet heads and an electrical signal is provided to the head pack and the head plate when the head pack is coupled to the head plate.
